(19) United States
(12) Patent Application Publication
(10) Pub. No.: US 2016/0050746 A1
(43) Pub. Date: Feb. 18, 2016

(54) Printed Circuit Assembly And A Touch Sensitive System Comprising The Assembly

(71) Applicant: FLATFROG LABORATORIES AB, Lund (SE)

(72) Inventors: Ola Wassvik, Brösarp (SE); Christer Fåhraeus, Bjärred (SE)

(21) Appl. No.: 14/783,751

(22) PCT Filed: Apr. 9, 2014
(86) PCT No.: PCT/SE2014/050437

§ 371 Date: Oct. 9, 2015

(30) Foreign Application Priority Data
Apr. 11, 2013 (SE) 1350460-0

(51) Int. Cl. H05K 1/02; H05K 3/28; H05K 3/34; G06F 3/042

(52) U.S. Cl. CPC H05K 1/0213; G06F 3/0421; H05K 3/284; H05K 3/341; H05K 1/028

(57) ABSTRACT

The disclosure relates to a printed circuit assembly, PCA, comprising: a printed circuit board, PCB; a group of components comprising an emitter, a detector and an integrated circuit, IC wherein the components are electrically bonded to the PCB, and the emitter and the detector are electrically connected to the integrated circuit via the PCB, the integrated circuit is further configured to control operation of the emitter and the detector in the same group, and a first coating covering at least one of the components in the group, wherein the first coating is made of an optically transparent material. The disclosure also relates to a method for fabricating a printed circuit assembly, and a touch sensitive system comprising the printed circuit assembly.

### CROSS-REFERENCE TO RELATED APPLICATIONS

The present application claims the benefit of Swedish patent application No. 1350460-0, filed 11 Apr. 2013.

### FIELD OF THE INVENTION

The present invention relates to a printed circuit assembly, and use of such assembly in a touch sensitive system according to the preamble of the independent claims.

### BACKGROUND OF THE INVENTION

Touch sensing systems (“touch systems”) are in widespread use in a variety of applications. Typically, the touch systems are actuated by a touch object such as a finger or stylus, either in direct contact, or through proximity (i.e. without contact), with a touch surface. Touch systems are for example used as touch pads of laptop computers, in control panels, and as overlays to displays on e.g. hand held devices, such as mobile telephones. A touch panel that is overlaid on or integrated in a display is also denoted a “touch screen”. Many other applications are known in the art. To an increasing extent, touch systems are designed to he able to detect two or more touches simultaneously, this capability often being referred to as “multi-touch” in the art.

WO2011/028169 and WO2011/049512 disclose multi-touch systems that are based on frustrated total internal reflection (FTIR). Light sheets are coupled into a panel by emitters to propagate inside the panel by total internal reflection (FIR). When an object comes into contact with a touch surface of the panel, the propagating light is attenuated at the point of touch. The transmitted light is measured at a plurality of outcoupling points by one or more light detectors. The signals from the light detectors are processed for input into an image reconstruction algorithm that generates a 2D representation of interaction across the touch surface. This enables repeated determination of current position/size/shape of touches in the 2D representation while one or more users interact with the touch surface. Examples of such touch systems are found in e.g. U.S. Pat. No. 3,673,327, U.S. Pat. No. 4,254,333 and U.S. Pat. No. 6,972,753.

The emitters and detectors of the system should be connected to external electrical circuitry. These components are typically integrated into and electrically connected to a printed circuit board, a PCB, and placed along the periphery of the touch panel.

Different solutions exist to integrate the components to the PCB. One category of solutions makes use of wire bonding to connect the component to external circuitry. One solution in this category use FR-4, a composite material composed of woven fiberglass cloth. A thin layer of copper foil is laminated to one, or both sides of an FR-4 glass epoxy panel. These are commonly referred to as “copper-clad laminates”. A component is connected via bonding wires to a FR-4 panel and forms with a molding a substrate package. The substrate package is in turn connected to the PCB via connections on the package.

Another solution in this category makes use of a lead frame package, where the component is connected via bonding wires to a lead frame. The component and bonding wires are protected by a molding. The lead frame is in turn connected to the PCB.

Another category of solutions for connecting components to external circuitry is to use flip chip, also known as controlled collapse chip connection, or its acronym, C4. The solution makes use of solder bumps that has been deposited to the external circuitry. In order to mount the chip to external circuitry, e.g. a PCB, it is flipped over so that its top side faces down, and aligned so that its pads align with matching pads on the external circuit, and then the solder is flowed to complete the interconnect.

The components and its wire bonding, if used, can be protected by so called glob-top coating. Glob-top is a coating consisting of a drop of specially formulated resin deposited over the chip and its wire bonds, to provide mechanical support and exclude contaminations such as fingerprint residues which could disrupt circuit operation.

The cost of each component, i.e. an emitter, detector or integrated circuit, is low compared to the cost of the rest of the package it is a part of It is also a time consuming process to first connect each component to its package, and secondly connect the package to the external circuitry, e.g., the PCB. If the PCB is a flexible film, connections between the package and the PCB may be exerted to mechanical stress if the flexible film is e.g. bent.

It is thus an object of the invention to reduce the cost for the system and to reduce the time for mounting the components. It is a further object to provide an incoupling solution to the system.

### SUMMARY OF THE INVENTION

According to a first aspect, the object is achieved by a printed circuit assembly, PCA comprising a printed circuit board, PCB, a group of components comprising an emitter, a detector and an integrated circuit, IC, wherein the components are electrically bonded to the PCB, and the emitter and the detector are electrically connected to the integrated circuit via the PCB. The integrated circuit is further configured to control operation of the emitter and the detector in the same group. The PCA further comprises a first coating covering at least one of the components in the group, where the first coating is made of an optically transparent material.

With a printed circuit assembly according to the invention, there is no need for any packaging of the components before they are bonded to the PCB. Further, the components are placed at predefined positions on the PCB such that the PCA can be immediately used in a touch sensitive system essentially without any time consuming positioning of each group of component to the system. The number of connections between the components and the PCB may be larger than if a package is used, and mechanical stress exerted on the PCA will be distributed on a larger number of connections making the PCA less vulnerable to the stress.

According to one embodiment, the optically transparent material is transparent to infra-red light.

According to one embodiment, the optically transparent material is configured to block visible light.

According to one embodiment , the first coating has a box-shaped form with two longitudinal side surfaces and a top surface, wherein at least one of the side surfaces and top surface is a substantially planar surface.

According to one embodiment, at least one of the components in the group are electrically bonded to the PCB via one or several wires from each component to the PCB.

According to one embodiment, the integrated circuit is covered with a second coating, wherein the second coating comprises an optically non-transparent material.

According to one embodiment, the PCB is a flexible printed circuit board.

According to one embodiment, the PCB has a longitudinal extension and comprises a plurality of groups of components, wherein the groups of components are positioned at a distance from each other along the longitudinal extension of the PCB.

According to a second aspect, at least part of the object is achieved by a touch sensitive system comprising a touch sensitive panel defining a touch surface and a printed circuit assembly according to any of the printed circuit assembly embodiments as described herein, wherein the printed circuit assembly is attached to the touch sensitive panel along the periphery of the touch surface, and a control unit connected to the integrated circuit in each group, and configured to control operation of the components in each group.

According to one embodiment, the touch sensitive system is based on Frustrated Total Internal Reflection, FTIR.

According to a third aspect, at least part of the object is achieved by a method for fabricating a printed circuit assembly, comprising

arranging at least one group of components comprising an emitter, a detector and an integrated circuit, IC, on a printed circuit board, PCB;

bonding the components of the at least one group to the PCB, such that the components are electrically bonded to the PCB, and the emitter and the detector are electrically connected to the integrated circuit via the PCB;

forming a first coating covering at least one of the components, wherein the first coating is made of an optically transparent material;

curing the first coating.

According to one embodiment, the step of forming a first coating comprises forming a first coating having a box-shaped form with two longitudinal side surfaces and a top surface, wherein at least one of the side surfaces and top surface is a substantially planar surface.

According to one embodiment, the curing step comprises either ultraviolet curing or heat curing.

Preferred embodiments are set forth in the dependent claims and in the detailed description.

### SHORT DESCRIPTION OF THE APPENDED DRAWINGS

Below the invention will be described in detail with reference to the appended figures, of which:

FIG. 1 illustrates a side view of a touch arrangement based on FTIR.

FIG. 2 illustrates a top view of the touch arrangement in FIG. 1.

FIG. 3 illustrates a printed circuit assembly according to some embodiments of the invention.

FIGS. 4A and 4B illustrates different attachment alternatives of the printed circuit assembly in FIG. 3.

FIG. 5 illustrates a touch sensitive system according to some embodiments of the invention.

FIG. 6 illustrates a method for fabricating a printed circuit board according to some embodiments of the invention.

### DETAILED DESCRIPTION OF PREFERRED EMBODIMENTS OF THE INVENTION

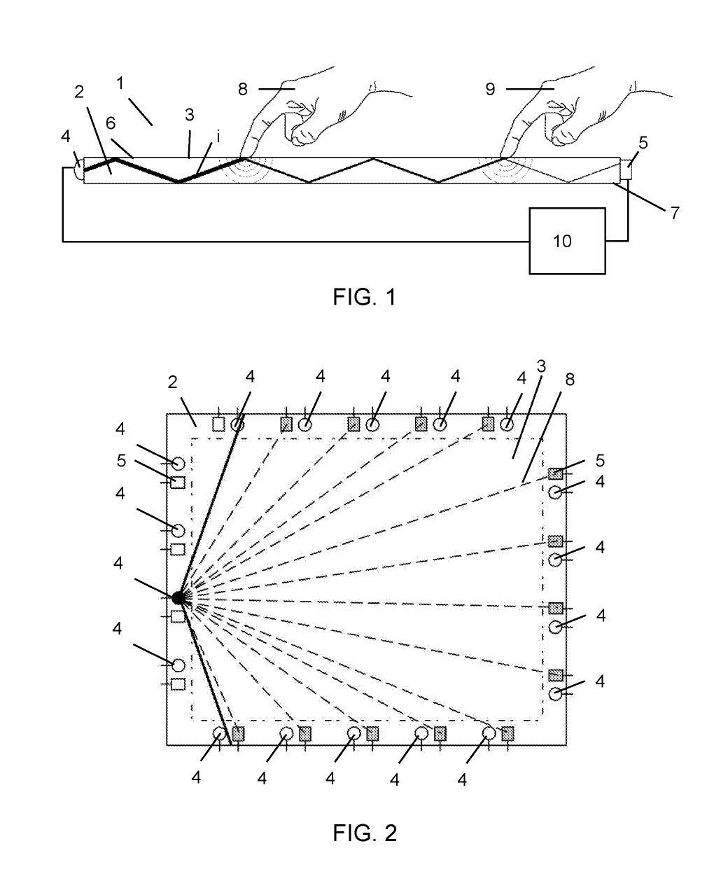

FIGS. 1 and 2 illustrates a side view and a top view of an example embodiment of a touch arrangement 1 to be used in a touch-sensitive system 11 that is based on the concept of FTIR (Frustrated Total Internal Reflection), also denoted “FTIR system”. The touch arrangement 1 operates by transmitting light inside a touch sensitive panel 2, from light emitters 4 to light sensors or detectors 5, so as to illuminate a touch surface 3 from within the panel 2. The panel 2 is made of solid material in one or more layers and may have any shape. The panel 2 defines an internal radiation propagation channel, in which light propagates by internal reflections. In the example of FIG. 1, the propagation channel is defined between two boundary surfaces 6, 7 of the panel 2, thus a top surface 6 and a bottom surface 7, where the top surface 6 allows the propagating light to interact with touching objects 27, 9 and thereby defines the touch surface 3. This is achieved by injecting the light into the panel 2 such that the light is reflected by total internal reflection (TIR) in the touch surface 3 as it propagates through the panel 2. The light may be reflected by TIR in the bottom surface 7 or against a reflective coating thereon. It is also conceivable that the propagation channel is spaced from the bottom surface 7, e.g. the panel 2 comprises multiple layers of different materials. The panel 2 may be designed to be overlaid on or integrated into a display device or monitor.

The arrangement 1 allows one or several objects 27, 9 that is brought into close vicinity of, or in contact with, the touch surface 3 to interact with the propagating light at the point of touch. In this interaction, part of the light may be scattered by the object 27, 9, part of the light may be absorbed by the object 27, 9 and part of the light may continue to propagate in its original direction across the panel 2. Thus, the touching object 27, 9 causes a local frustration of the total internal reflection, which leads to a decrease in the energy (power/intensity) of the transmitted light, as indicated by the thinned lines downstream of the touching objects 27, 9 in FIG. 1. If two objects 27 and 9 happen to be placed after each other along a light path i from an emitter 4 to a detector 5, part of the light will interact with both these objects 27, 9. Provided that the light energy is sufficient, a remainder of the light will interact with both objects 27, 9 and generate an output signal that allows both interactions (touch inputs) to be identified. The output signal is received to a control unit 10 which processes the output signal to detect interaction with the touching object(s) 27, 9.

As illustrated in FIG. 2, the emitters 4 are distributed along the perimeter of the touch surface 3 of the panel 2. The emitters 4 generate a corresponding number of light sheets inside the panel 2. Each emitter 4 generates a beam of light that expands in the plane of the panel 2 while propagating in the panel 2. Each beam propagates from one or more entry or incoupling points on the panel 2. The detectors 5 are distributed along the perimeter of the touch surface 3 of the panel 2 to receive the light from the emitters 4 at a number of spaced-apart outcoupling points on the panel 2. The emitters 4 and detectors 5 are here grouped in couples with one emitter 4 and one detector S side by side, but the distribution could be different. For example, two or three emitters 4 located side by side, and two or three detectors 5 located side by side could be alternately distributed along the perimeter of the touch surface 3. A light path from an emitter 4 to a detector 5 is defined as a detection line 8. In the figure the detection lines 8 from one emitter 4 to a plurality of detectors 5 are denoted as dotted lines. The plurality of detectors 5 are shaded to indicate their participation in receiving light at ends of the detection lines 8.

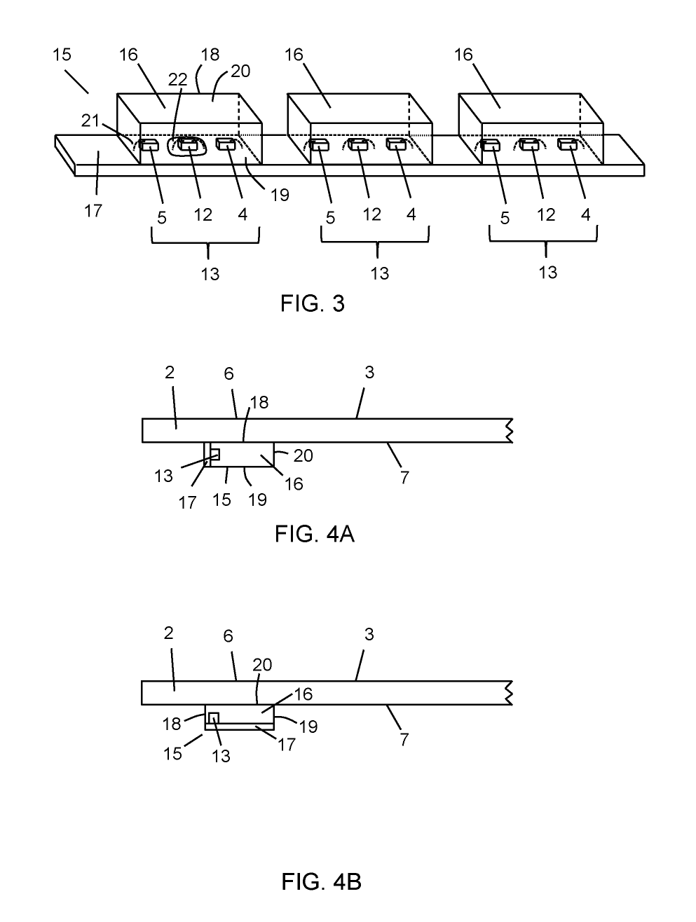

In FIG. 3 an example of a printed circuit assembly, PCA, 15 is shown. The PCA 15 comprises a printed circuit board, PCB, 17, and at least one group 13 of components comprising an emitter 4, a detector 5 and an integrated circuit, IC, 12. In FIG. 3 three groups 13 of components are illustrated, but it is understood that the number can be more or less. The PCB 17 may have a longitudinal extension and comprise a plurality of groups 13 of components. The groups 13 of components are then positioned at a distance from each other along the longitudinal extension of the PCB 17. The PCB 17 may he a flexible printed circuit board. The term “flexible” means that the assembled PCB 17, thus the PCA 15, will be able to bend without breaking. A suitable material for the flexible printed circuit board is e.g. flexible plastic substrates such as polyimide, polymer thermoplastics such as PEEK (Polyether ether ketone), or polyester film. The PCA 15 may be used with the arrangement 1 in FIGS. 1 and 2 to inject light into the panel 2 and to detect the same. One or several of the components may be electrically bonded to the PCB 17 via wire bonding where one or several wires 21 from the components are connected to the PCB 17 via pads. Alternatively, one or more of the components may be electrically bonded to the PCB 17 via so called flip chip bonding, via matching soldering pads on the PCB 17 and the components). In any of the alternatives, the components are connected directly to the PCB 17 without any intermediate attachment means. The emitter 4 and the detector 5 are electrically connected to the integrated circuit 12 via the PCB 17. The integrated circuit 12 is configured to control operation of the emitter 4 and the detector 5 in the same group 13. The PCB 17 is thus used to mechanically support the components and to electrically connect the components. To electrically connect the components, the PCB 17 may comprise conductive pathways, tracks or signal traces e.g. etched from copper sheets laminated onto a non-conductive substrate.

The PCA 15 further comprises a first coating 16 covering at least one of the components in the group 13. The first coating 16 is made of an optically transparent material, such that the emitter 4 can emit light into the panel 2 via the first coating 16, and the detector 5 can detect light propagating in the panel 2 via the first coating 16. The optically transparent material is preferably transparent to near infra-red light, thus, it lets through electromagnetic radiation with the wavelengths from 0.74 μm to 1.4 μm. Example of such materials are e.g. a polymer, epoxy, etc. The first coating 16 may additionally comprise a material that is blocking visible light.

The integrated circuit 12 may be covered with a second coating 22. The second coating 22 may be located between the first coating 16 and the integrated circuit 12 as illustrated in FIG. 3. Alternatively, the integrated circuit 12 is only covered by the second coating 22, and thus not with a first coating 16. The second coating 22 is only illustrated on one of the integrated circuits 12 on the PCA 15, but it is understood that all the integrated circuits 12 on the PCA 15 may be covered with a second coating 22. The second coating 22 comprises an optically non-transparent material, such that the integrated circuit 12 will be protected from light. Light might otherwise disturb the function of the integrated circuit 12. The second coating 22 may be deposited to the integrated circuit 12 as a so called glob-top coating. The glob-top coating consisting of a drop of e.g. specially formulated resin with filter characteristics such that no light is allowed to pass. For example may a black color be used as a filter agent mixed to the resin.

The first coating 16 may have a box-shaped form with two longitudinal side surfaces 18, 19 and a top surface 20. At least one of the side surfaces 18, 19 and top surface 20 is a substantially planar surface, such that it can act as an optically surface and lie against the panel 2. In FIGS. 4A and 4B, two different alternatives for attaching the PCA 15 to the panel 2 are schematically illustrated. In the figures the PCA 15 is illustrated in cross-section, where one component in a group 13 is shown, as well as the first coating 16 and the PCB 17. In FIG. 4A, the PCA 15 is placed such that one side surface 18 faces the bottom surface 7 of the panel 2. Light from an emitter 4 and light to a detector 5 in the group 13 may then be transmitted into and out of the panel 2 via the side surface 18 that faces the bottom surface 7. The PCB 17 is here placed in a direction to the periphery of the panel 2, in FIG. 4B the PCA 15 is placed such that the top surface 20 faces the bottom surface 7 of the panel 2. Light from an emitter 4 and light to a detector 5 in the group 13 may then be transmitted into and out of the panel 2 via the top surface 20 that faces the bottom surface 7. The PCB 17 is here placed in a direction away from the bottom surface 7 of the panel 2.

An adhering means such as glue or double coated adhesive tape may he used between the PCA 15 and the bottom surface 7 of the panel 2 to attach the PCA 15 to the panel 2 as previously illustrated. The adhering means may also act as a filler to fill in any irregularities in the surface of the PCA 15 facing the bottom surface 7 to create a tight attachment, and enable coupling of light from the emitter 4 to the panel 2 and from the panel 2 to the detector 5.

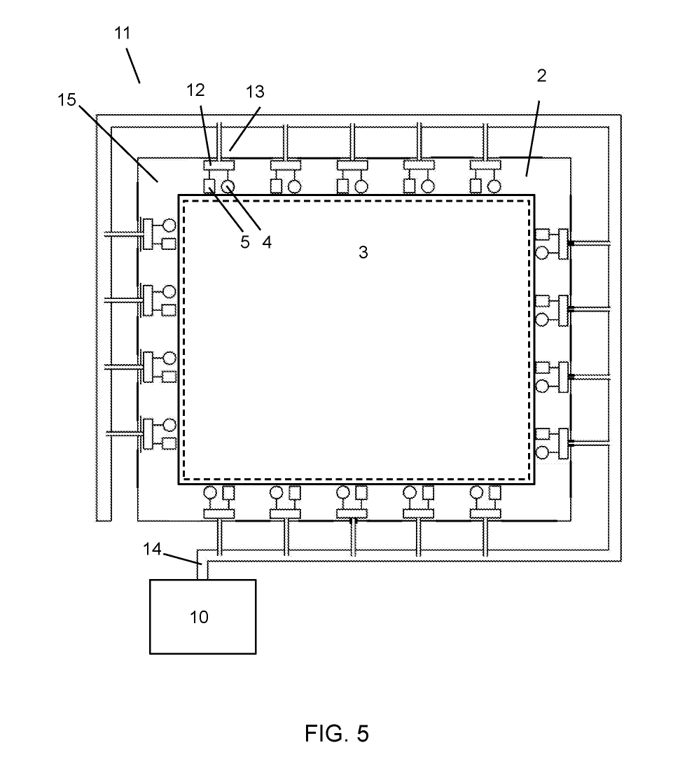

The PCA 15 with a plurality of groups 13 of components may be placed around the periphery of the touch surface 3 or the panel 2, such that light from emitters 4 is injected into the panel 2 etc. as previously explained. This is illustrated in FIG. 5, where a touch sensitive system 11 comprising a touch sensitive panel 2 defining a touch surface 3 is shown. The system 11 comprises a printed circuit assembly 15 according to any of the embodiments previously explained. The printed circuit assembly 15 is attached to the touch sensitive panel 2 along the periphery of the touch surface 3. The system 11 further comprises a control unit 10. The control unit 10 may be connected to one or several integrated circuits 12 via a buss 14, daisy chain or via other wired connections. The integrated circuits 12 may be connected in series, or in parallel, via the buss 14, daisy chain or other wired connection to the one or several integrated circuits 12 connoted to the control unit 10. The integrated circuits 12 may be arranged to communicate via a local area network, e.g. a token ring network. The control unit 10 is configured to control operation of the components in each group 13. The control unit 10 is further configured to receive detection data from the detectors 5 via e.g. one or several signals, and to analyse the detection data to detect interaction with the touch surface 3. The touch sensitive system 11 is according to one embodiment based on Frustrated Total Internal Reflection, FTIR.

A screen or display may be integrated with the panel 2, e.g. attached to the bottom surface 7 of the panel 2. The PCA 15 is then preferably placed along the panel 2 outside the extension of the screen or display. If e.g. an 11 inch screen or display is used, the number of emitters 4 may be between 40-80, and the number of detectors 5 may be between 40-80 to cover the total area of the screen or display. Each integrated circuit 12 may be connected to 1-4 emitters 4 each, and 1-4 detectors 5. According to one embodiment, only one emitter 4 and one detector 5 is connected to each integrated circuit 12.

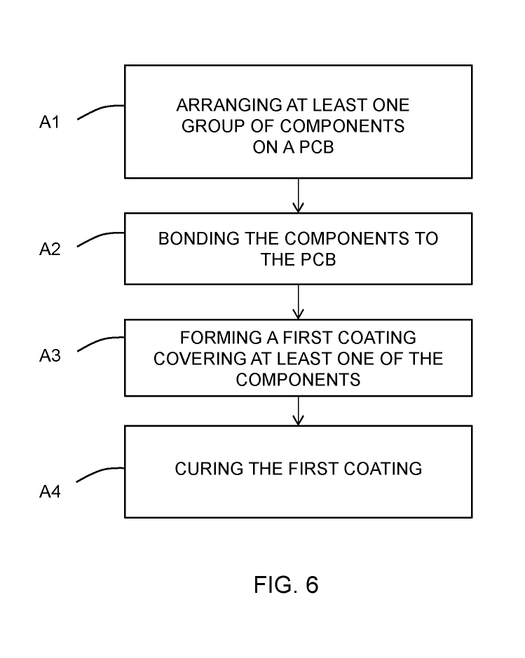

The disclosure also relates to a method for fabricating a printed circuit assembly 15. The method is here explained with reference to the flowchart in FIG. 6. The method comprises arranging at least one group of components 13 comprising an emitter 4, a detector 5 and an integrated circuit, IC, 12 on a printed circuit board, PCB, 17 (A1). The components may be arranged in different manners, for example side by side as illustrated in FIG. 3, or with the integrated circuit 12 in parallel with the emitter 4 and detector 5 as shown in FIG. 5. Other arrangements are also feasible, and the illustrated arrangements are only for illustration. The arrangement preferably matches how the components later on shall be located in the system 11. For example, the arrangement may include the distance between each group 13 of components, and distances between each of the components in a group 13. The PCB 17 is prepared with pads and conductive pathways etc. to enable electrical connection between the PCB 17 and the components, and between the components. The components are thus arranged such that they match with the premade soldering spots in a pre-defined pattern. Thus, there is no need for any intermediate layer between the components and the PCB 17, or any intermediate step of attaching the components to any holding means or other attachments in a package. The components of at least one group 13 are then electrically bonded to the PCB 17, and the emitter 4 and the detector 5 are electrically connected to the integrated circuit 12 via the PCB 17 (A2). This step can be made by e.g. heating the soldering spots. Hereafter, a first coating 16 is formed covering at least one of the components, wherein the first coating 16 is made of an optically transparent material (A3). The optically transparent material is preferably transparent to infra-red light but blocking to visible light. The first coating 16 may be formed to have a box-shaped form as illustrated in FIG. 3, with two longitudinal side surfaces 18, 19 and a top surface 20, wherein at least one of the side surfaces 18, 19 and top surface 20 is a substantially planar surface. This box-shaped form may be achieved with a method called “dam and fill” used to encapsulate components. To create a dam, a rectangle of fluid is dispensed around the component. This fluid is typically high viscosity in nature, so once it is dispensed, it does not flow. Liquid fill encapsulant, i.e. the material of the first coating, is then dispensed at high speed over the component and its wires, if any, to encapsulate them. The dam will keep the fluid in place. Another alternative is to cover the component with a box-like form, and to inject encapsulant into the form. The first coating 16 is then cured (A4). The curing step comprises for example ultraviolet (UV) curing or heat curing. Heat curing may be performed at room temperature.

The present invention is not limited to the above-described preferred embodiments. Various alternatives, modifications and equivalents may be used. Therefore, the above embodiments should not be taken as limiting the scope of the invention, which is defined by the appending claims.

1. A printed circuit assembly, comprising:
a printed circuit board (PCB);
a group of components comprising an emitter, a detector and an integrated circuit, wherein the components are electrically bonded to the PCB, the emitter and the detector are electrically connected to the integrated circuit via the PCB, and the integrated circuit is configured to control operation of the emitter and the detector in the group; and
a first coating covering at least one of the components in the group, wherein the first coating comprises an optically transparent material.

2. The printed circuit assembly according to claim 1, wherein the optically transparent material is transparent to infra-red light.

3. The printed circuit assembly according to claim 1, wherein the optically transparent material is configured to block visible light.

4. The printed circuit assembly according to claim 1, wherein the first coating has a box-shaped form with two longitudinal side surfaces and a top surface, wherein at least one of the side surfaces and top surface is a substantially planar surface.

5. The printed circuit assembly according to claim 1, wherein at least one of the components in the group is electrically bonded to the PCB via one or more connections.

6. The printed circuit assembly according to claim 1, wherein the integrated circuit is covered with a second coating, wherein the second coating comprises an optically non-transparent material.

7. The printed circuit assembly according claim 1, wherein the PCB is a flexible printed circuit board.

8. The printed circuit board according to claim 1, wherein the PCB has a longitudinal extension and comprises a plurality of groups of components, wherein the groups of components are positioned at a distance from each other along the longitudinal extension of the PCB.

9. A touch sensitive system comprising:
a touch sensitive panel defining a touch surface;
a printed circuit assembly according to claim 1, wherein the printed circuit assembly is attached to the touch sensitive panel along the periphery of said touch surface; and
a control unit connected to the integrated circuit in one or more groups, and configured to control operation of the components in each of said one or more groups.

10. The touch sensitive system according to claim 9, wherein said touch sensitive system is based on Frustrated Total Internal Reflection.

11. A method for fabricating a printed circuit assembly, comprising:
arranging at least one group of components comprising an emitter, a detector and an integrated circuit on a printed circuit board (PCB);
bonding the components of the at least one group to the PCB such that the components are electrically bonded to the PCB and the emitter and the detector are electrically connected to the integrated circuit via the PCB;
forming a first coating covering at least one of the components, wherein the first coating is made of an optically transparent material; and
curing the first coating.

12. A method according to claim 11, wherein the step of forming a first coating comprises forming a first coating having a box-shaped form with two longitudinal side surfaces and a top surface, wherein at least one of the side surfaces and top surface is a substantially planar surface.

13. A method according to claim 11, wherein the curing step comprises either ultraviolet curing or heat curing.
